(19) United States
(12) Patent Application Publication
(10) Pub. No.: US 2002/0174953 A1
(43) Pub. Date: Nov. 28, 2002

(54) Wafer chuck having refrigerating plate serving as chucking plate

(75) Inventor: Shunji Yamada, Hadano-shi (JP)

Correspondence Address: ARENT FOX KINTNER PLOTKIN & KAHN, PLLC, 1050 Connecticut Avenue, N.W., Suite 600, Washington, DC, 20036-5339, US

(73) Assignee: Sumitomo Heavy Industries, Ltd.

(21) Appl. No.: 10/141,824

(22) Filed: May 10, 2002

(30) Foreign Application Priority Data
May 23, 2001 (JP) 153471/2001

(51) Int. Cl. C23F 1/00; C23C 16/00

(52) U.S. Cl. 156/345.53; 118/724; 118/725; 118/728; 156/345.52; 156/345.51

(57) ABSTRACT

In a wafer chuck, a vacuum chucking plate is used as an upper heat conductive plate of a refrigerating plate. A base supports the refrigerating plate with protruding portions which are formed on an upper surface thereof and fixed to a lower surface of the refrigerating plate. The protruding portions form a space between said lower surface of the refrigerating plate and the upper surface of the base. A rubber heater is attached to the lower surface of the refrigerating plate in the space. With this structure, the number of parts is reduced and it becomes easy to manufacture.

### BACKGROUND OF THE INVENTION

This invention relates to a wafer chuck for chucking a semiconductor wafer and, particularly, to an improvement of the wafer chuck.

In semiconductor device manufacturing, a plurality of semiconductor devices having the same structure is generally produced all together on a semiconductor wafer (e.g. a silicon wafer). Before the semiconductor devices on the semiconductor wafer are cut into individual devices, a final electrical test (or a functional test) is performed to measure electrical characteristics of the semiconductor devices and/or to judge qualities of the semiconductor devices. The electrical test is performed by using a wafer prober and a wafer tester. The wafer prober holds the semiconductor wafer to move it and to control temperature of it (or to heat and/or cool it). The wafer tester measures electric characteristics of the semiconductor devices on the semiconductor wafer held by the wafer prober.

The wafer prober comprises an X-Y table which can be minutely moved in a plane. The X-Y table provides a wafer chuck attached thereon. The wafer chuck chucks or holds the semiconductor wafer put thereon by the use of vacuum power. The wafer chuck can not only hold or fix the semiconductor wafer but also heat/cool the semiconductor wafer.

An existing wafer chuck comprises a vacuum chucking plate for chucking the semiconductor wafer, a heater for heating the semiconductor wafer via the vacuum chucking plate, and a refrigerating plate for refrigerating the semiconductor wafer via both of the heater and the vacuum chucking plate. The vacuum chucking plate is laid on the heater which is laid on the refrigerating plate.

For normal function of the wafer chuck, it is necessary that the vacuum chucking plate, the heater and the refrigerating plate are individually formed with great precision according to the design specifications. Therefore, the existing wafer chuck has a problem that many complex processes are necessary to manufacture the wafer chuck.

### SUMMARY OF THE INVENTION

It is therefore an object of this invention to provide a wafer chuck capable of reducing complex processes in a manufacturing process thereof.

Other object of this invention will become clear as the description proceeds.

According to an aspect of this invention, a wafer chuck is for chucking and refrigerating a semiconductor wafer and comprises a chucking portion which has an upper surface and a lower surface and which chucks the semiconductor wafer. A refrigerating portion is laid on the lower surface of the chucking portion and has a flow path at the inside thereof to refrigerate the semiconductor wafer via the chucking portion by passing refrigerant through the flow path. The chucking portion is used to a part of the flow path.

According to another aspect of this invention, a wafer refrigerating plate is for use in a wafer chuck and comprises an upper heat conductive plate which has an upper surface and a lower surface and which chucks a semiconductor wafer on the upper surface. A lower heat conductive plate has an upper surface and is located under the upper heat conductive plate parallel to the upper heat conductive plate. An intermediate portion is located between said upper heat conductive plate and the lower heat conductive plate and fixed to the lower surface of the upper heat conductive plate and the lower heat conductive plate. The intermediate portion forms a flow path between said lower surface of the upper heat conductive plate and the upper surface of the lower heat conductive plate to pass a refrigerant through.

### BRIEF DESCRIPTION OF THE DRAWING

FIG. 1 is an exploded perspective view of an existing wafer chuck;

FIG. 2 is a vertical sectional view of the existing wafer chuck of FIG. 1;

FIG. 3 is an exploded perspective view of a wafer chuck of a preferred embodiment of this invention;

FIG. 4 is a vertical sectional view of the wafer chuck of FIG. 3; and

FIG. 5 is a plane view of a refrigerating portion used in the wafer chuck of FIG. 3.

### DESCRIPTION OF THE PREFERRED EMBODIMENT

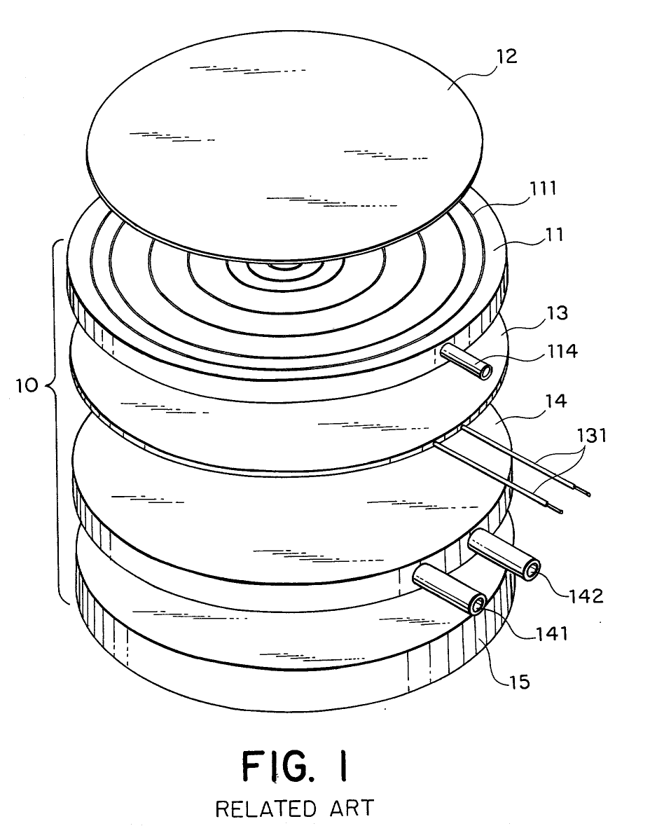

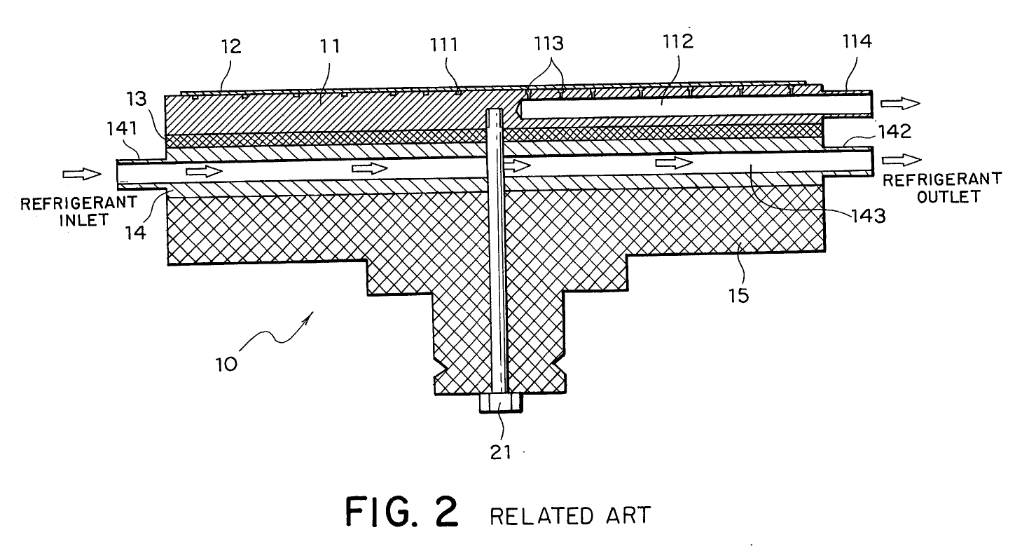

Referring to FIGS. 1 and 2, description will be at first directed to an existing wafer chuck for a better understanding of this invention. The existing wafer chuck is mounted on a driving surface of an X-Y table of a wafer prober (not shown).

As illustrated in FIGS. 1 and 2, an existing wafer chuck 10 comprises a chucking plate 11 for chucking a silicon wafer 12 by the use of vacuum power. A heater 13 on which the chucking plate 11 is laid is for heating the silicon wafer 12 via the chucking plate 11. A refrigerating plate 14 on which the heater 13 is laid is for refrigerating the silicon wafer 12 via both of the heater 13 and the chucking plate 11. A ceramic base 15 on which the refrigerating plate 14 is laid is for supporting a combination of the refrigerating plate 14, the heater 13 and the chucking plate 11. The combination of the chucking plate 11, the heater 13 and the refrigerating plate 14 is securely fixed to the ceramic base 15 by a fixing bolt 21 as shown in FIG. 2.

The chucking plate 11 has a disk shape with upper and lower surfaces. The upper surface of the chucking plate 11 is precisely smoothed by lapping or the like to certainly hold the silicon wafer 12 without causing partial stress to the silicon wafer 12. Furthermore, the lower surface of the chucking plate 11 is precisely formed to be parallel to the upper surface. High degree of parallel between the upper and the lower surfaces of the chucking plate 11 makes easy to parallel the upper surface with the driving surface of the X-Y table of the wafer prober.

The chucking plate 11 provides a plurality of concentric circular grooves 111 in the upper surface and a vacuum evacuating bore 112 at the inside thereof. The vacuum evacuating bore 112 extends from about the center to an outer circumference surface of the chucking plate 11. The vacuum evacuating bore 112 is connected to bottoms of the concentric circular grooves 111 through connecting holes 113. On the outer circumference surface of the chucking plate 11, a vacuum outlet 114 is formed to be continuous with the vacuum evacuating bore 112.

The chucking plate 11 is made of a material having a high heat conductivity to have a uniform distribution of surface temperature. The material is, for example, an aluminum alloy or a copper alloy. The uniform surface temperature of the chucking plate 11 makes possible to equally exchange heat with the silicon wafer 12 held by the chucking plate 11.

Upon assembling the wafer chuck 10 into the wafer prober, the vacuum outlet 114 is connected to a vacuum pump (not shown) with a pipe or tube such as a urethane tube or the like. When the vacuum pump evacuates the vacuum evacuating bore 112, the air existing in the grooves 111 is drawn into the vacuum evacuating bore 112 through the connecting holes 113. In this event, if the grooves 111 are covered with the silicon wafer 12, internal pressures of the grooves 111 are lower than the outer pressure. Consequently, the silicon wafer 12 is held or fixed by the chucking plate 11 with the vacuum power. The silicon wafer 12 is easy to removed by stopping the vacuum pump or by disconnecting the vacuum pump from the chucking plate 11 by using an electromagnetic valve or the like located at the pipe.

The heater 13 has a disk member, such as a ceramic disk or the like, and a heating element (not shown), such as a Nichrome wire or the like, embedded in the disk member. The disk member has upper and lower surfaces. The upper surface of the disk member is precisely smoothed to be close to the lower surface of the chucking plate 11 without gap. It is desirable that there is no gap between the heater 13 and the chucking plate 11 because a gap reduces heat transfer coefficient between them. On the other hand, the lower surface of the heater 13 is precisely formed to be parallel with the upper surface of the heater 13. The lower surface parallel to the upper surface makes easy to parallel the upper surface of the vacuum chucking plate 11 with the driving surface of the X-Y table of the wafer prober.

The heating element of the heater 13 is connected to a pair of leads 131 extending to the outside of the disk member. Upon supplying electric current between the leads 131, the heating element generates heat and thereby the heater 13 heats the silicon wafer 12 via the chucking plate 11. The heater 13 uses for not only heating the silicon wafer 12 to a high temperature but also controlling the temperature of the silicon wafer 12 when it is refrigerated by the refrigerating plate 14 as described below. That is, the heating element is used for finely control of the temperature of the silicon wafer 12 when the refrigerating plate 14 refrigerates the silicon wafer 12. Additionally, the refrigerating plate 14 is not used when the silicon wafer 12 is heated to the high temperature.

The refrigerating plate 14 has a disk shape and upper and lower surfaces. The upper and the lower surfaces of the refrigerating plate 14 are precisely formed parallel to each other. This is for obtaining high heat transfer coefficient between the refrigerating plate 14 and the heater 13. In addition, this is for making easy to parallel the upper surface of the chucking plate 11 with the driving surface of the X-Y table.

The refrigerating plate 14 has a refrigerant inlet 141 and a refrigerant outlet 142 which are formed on the outer circumference surface thereof. The refrigerating plate 14 provides an inner flow path 143 which carries a refrigerant from the refrigerant inlet 141 to the refrigerant outlet 142.

In FIG. 2, the inner flow path 143 is depicted as a single straight path. However, actual inner flow path is bent at a plurality of points or parts or has a plurality of branch paths so that the refrigerating plate 14 has large heat-transfer area and uniform temperature distribution. Furthermore, actual refrigerant inlet and outlet are generally arranged adjacent to each other as shown in FIG. 1.

The refrigerating plate 14 comprises a main body and a shell for receiving the main body though they are not illustrated in FIGS. 1 and 2. Like the chucking plate 11, the main body is made of the material with the high heat conductivity. The material is, for example, the aluminum alloy or the copper alloy. Use of the material with the high heat conductivity causes a uniform temperature distribution in the refrigerating plate 14 and efficient heat exchange between the refrigerant and the refrigerating plate 14. On the other hand, the shell is made of another material with high stiffness. The shell is made of, for example, a thin plate of stainless steel. The main body and the shell are individually formed by joining or soldering plural parts.

Upon assembling the wafer chuck 10 into the wafer prober, the refrigerant inlet 141 and outlet 142 are coupled to a refrigerant circulating apparatus (not shown). The refrigerant circulating apparatus makes refrigerant circulate through the inner flow path 143 of the refrigerating plate 14. The refrigerant supplied from the refrigerant circulating apparatus into the inner flow path 143 exchanges heat with the refrigerating plate 14. In other words, the refrigerating plate 14 is refrigerated by the refrigerant supplied from the refrigerant circulating apparatus.

It is desirable that the chucking plate 11, the heater 13 and the refrigerating plate 14 are strongly fixed to one another and in contact with one another without gaps to obtain good heat transfer coefficients among them. If the chucking plate 11, the heater 13 and the refrigerating plate 14 are fixed by gluing or soldering one another, change of their temperature warps the wafer chuck 10. This is because the chucking plate 11, the heater 13 and the refrigerating plate 14 have different thermal expansion coefficients. Thus, in the existing wafer chuck 10, the chucking plate 11, the heater 13 and the refrigerating plate 14 are fixed to one another together with the ceramic base 15 by the fixing bolt 21.

The ceramic base 15 has an upper surface for laying the refrigerating plate 14. The upper surface of the ceramic base 15 is precisely smoothed to easily parallel the upper surface of the chucking plate 11 with the driving surface of the X-Y table. The ceramic base 15 further has a fixing section (or a protruding section protruding downwards in FIG. 2) at an underside thereof. The fixing section is fixed to the X-Y table with high stiffness.

As mentioned above, in manufacturing the existing wafer chuck 10, each part must be formed with high accuracy. Therefore, a lot of time and labor are necessary to manufacture the existing wafer chuck 10. Accordingly, the existing wafer chuck is expensive.

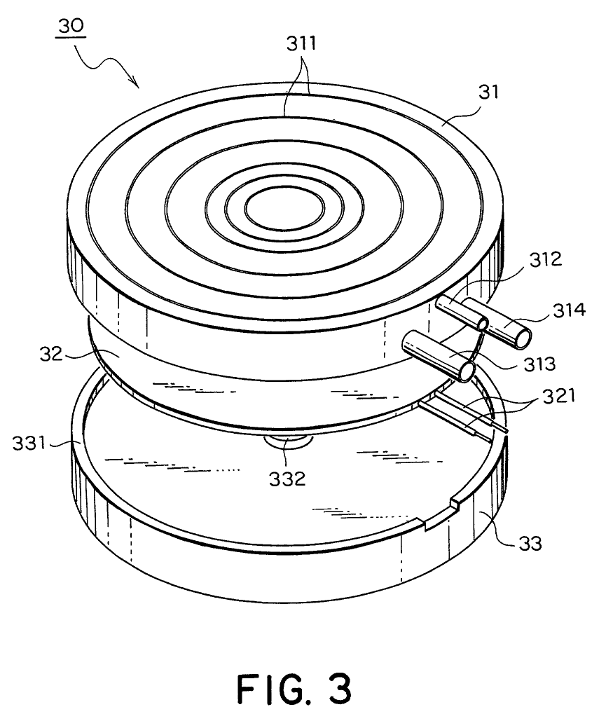

Referring to FIGS. 3 through 5, the description will proceed to a wafer chuck according to a preferred embodiment of this invention.

FIG. 3 is an exploded perspective view of the wafer chuck 30. As illustrated in FIG. 3, the wafer chuck 30 comprises a unified chucking and refrigerating plate 31 (hereinafter referred to simply as the refrigerating plate 31), a heater 32 and a ceramic base 33.

The refrigerating plate 31 serves as both of the chucking plate 11 and the refrigerating plate 14 of the existing wafer chuck of FIG. 1. It may be considered that the chucking plate 11 and the refrigerating plate 14 are unified into the refrigerating plate 31 by laying the vacuum chucking plate 11 on the refrigerating plate 14 and by sharing at least one part of them.

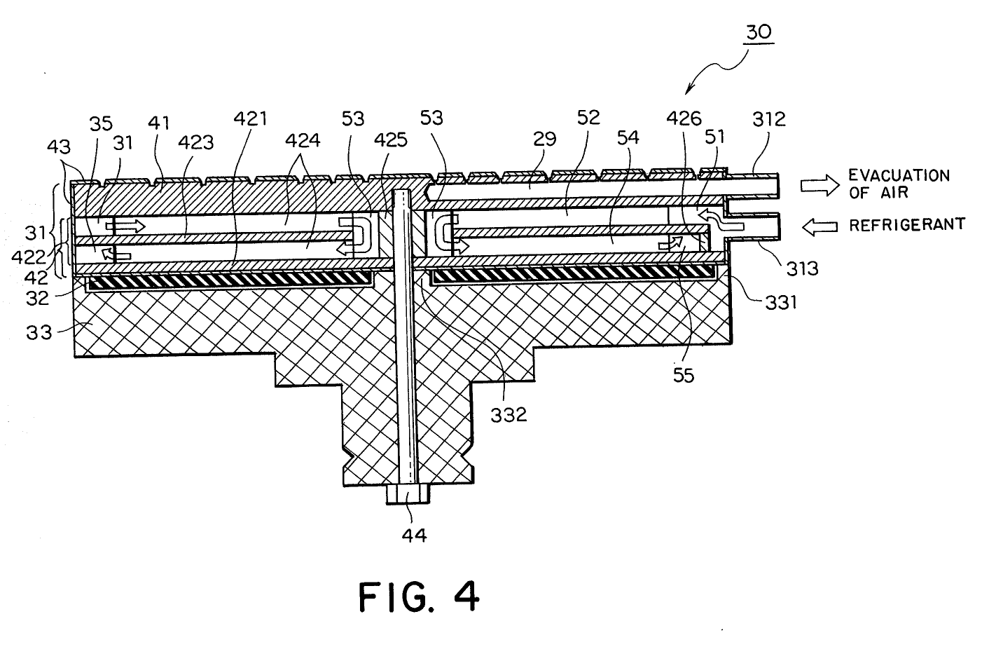

The refrigerating plate 31 has an upper surface in which a plurality of concentric circular grooves 311 is formed. The refrigerating plate 31 further provides a vacuum outlet 312, a refrigerant inlet 313 and a refrigerant outlet 314 projected from a circumference surface to the outside. The vacuum outlet 312 has a hollow continuous with a vacuum evacuating bore (see FIG. 4) leading to the concentric circular grooves 311. The refrigerant inlet 313 and outlet 314 are connected to both ends of an inner flow path formed inside the refrigerating plate 31. The upper surface of the refrigerating plate 31 is finished by lapping treatment to be smoothed with high accuracy. The refrigerating plate 31 further has a lower surface precisely parallel to the upper surface.

The heater 32 is different from the heater 13 of FIG. 1 and comprises an annular member made of a silicone rubber and a Nichrome foil embedded into the annular member as a heating member. The Nichrome foil is connected to a pair of leads 321 which extend from the circumferential surface of the annular member to the outside. The heater 32 does not necessarily need upper and lower surfaces precisely parallel to each other.

The ceramic base 33 has a circumferential protruding portion 331 and a center circular projection 332 on an upper surface thereof to correspond to the shape of the heater 32. The circumferential protruding portion 331 and the center circular projection 332 are precisely formed to have a common height larger than a thickness of the heater 32. This structure makes possible to use an inexpensive rubber heater as the heater 32.

FIG. 4 is a vertical sectional view of the wafer chuck of FIG. 3.

As illustrated in FIG. 4, the refrigerating plate 31 comprises an upper heat conductive plate 41 as a vacuum chucking portion, a refrigerating portion 42 unified with the upper heat conductive plate 41 and a shell 43 for receiving a combination of the upper heat conductive plate 41 and the refrigerating portion 42.

The upper heat conductive plate 41 has the same structure as the vacuum chucking plate 11 of FIG. 1. The upper heat conductive plate 41 is unified with the refrigerating portion 42 to form a refrigerating plate 31.

The refrigerating portion 42 comprises a lower heat conductive plate 421 and an intermediate portion 422 mounted on the lower heat conductive plate 421. The intermediate portion 422 is fixed not only to an upper surface of the lower heat conductive plate 421 but also to a lower surface of the upper heat conductive plate 41.

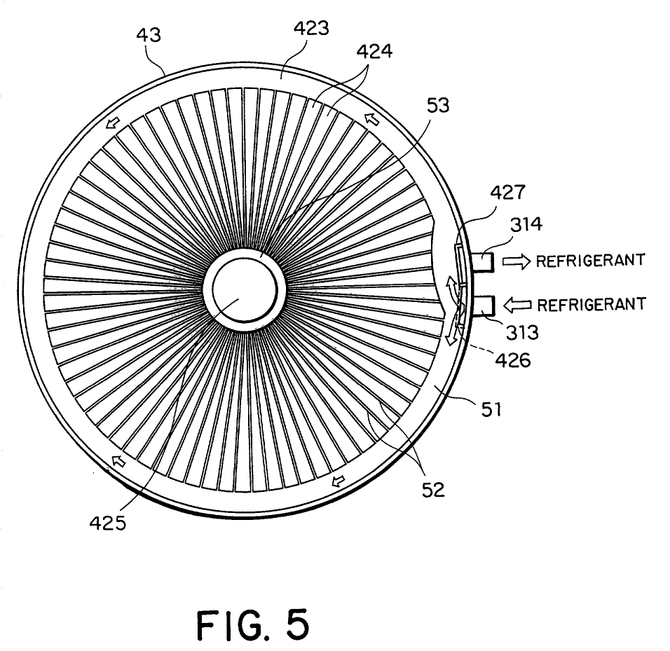

The intermediate portion 422 comprises an intermediate plate 423 having annular disk shape, a plurality of sector members 424, a cylindrical member 425 and hinder members 426 and 427. The sector members 424 are divided into two groups. One of the groups is located between the lower heat conductive plate 421 and the intermediate plate 423 while the other group is located between the intermediate plate 423 and the upper heat conductive plate 41. The sector members 424 of each group are arranged in a circle as shown in FIG. 5 to form radial branches in inner flow path of the lower heat conductive plate 421. The cylindrical member 425 fixed to the lower surface of the upper heat conductive plate 41 at the center and to the upper surface of the lower heat conductive plate 421 through a center hole of the intermediate plate 423. The hinder members 426 and 427 are located nearby the refrigerant inlet 313 and outlet 314, respectively.

The upper heat conductive plate 41 and the components of the refrigerating portion 42 are made of a material with high heat conductivity. For example, the material is an aluminum alloy or a copper alloy. The upper heat conductive plate 41 and the components of the refrigerating portion 42 are fixed to one another by soldering or gluing.

The shell 43 is made of another material with high stiffness. For instance, the material is stainless steel. The shell 43 receives or covers the unity of the upper heat conductive plate 41 and the refrigerating portion 42 and is fixed to them by soldering or gluing.

The heater 32 is tightly fixed to the lower surface of the refrigerating plate 31 to obtain good heat transfer coefficient between them. For example, adhere, such as a silicone rubber and so on, can be used to fix the heater 32 to the refrigerating plate 31.

The refrigerating plate 31 to which the heater 32 is attached is fixed to the ceramic base 33 by a fixing bolt 44. In this case, the circumferential protruding portion 331 and the center circular projection 332 of the ceramic base 33 support the refrigerating plate 31. When the common height of the circumferential protruding portion 331 and the center circular projection 332 is larger than the thickness of the heater 32, there is a space between the heater 32 and the ceramic base 33. The space prevents heat from transferring from the heater 32 to the ceramic base 33.

The ceramic base 33 has a fixing portion at the lower part. The fixing portion of the ceramic base 33 is rigidly fixed to an X-Y table of a wafer prober (not shown) with high accuracy.

Next, the operation of the wafer chuck is described below with referring to FIGS. 3 to 5.

At first, a semiconductor wafer (e.g. a silicon wafer) is put on the upper surface of the refrigerating plate 31 to cover at least one of the grooves 311. The grooves 311 covered with the semiconductor wafer are evacuated by a vacuum pump (not shown) and thereby the refrigerating plate 31 holds the semiconductor wafer.

To refrigerate the semiconductor wafer, a refrigerant circulating apparatus (not shown) refrigerates refrigerant to a predetermined temperature which is lower than a target temperature by a few degrees and decided in consideration with the environmental temperature. The refrigerant circulating apparatus supplies the refrigerant to the refrigerant inlet 333 of the refrigerating plate 31.

The refrigerant supplied to the refrigerant inlet 313 flows in a circumferential path 51 as shown by arrows in FIGS. 4 and 5. In this event, the hinder member 426 stops the refrigerant from going into between the intermediate plate 423 and the lower heat conductive plate 421. In the meantime, the hinder member 427 stops the refrigerant from going into the refrigerant outlet 314.

Because the circumferential path 51 has a cross section which is considerably larger than that of each radial branch 52, the refrigerant flows in the circumferential path 51 rather than the radial branches 52. Accordingly, the circumferential path 51 is immediately filled with the refrigerant.

After the circumferential path 51 is filled with the refrigerant, the refrigerant flows in the radial branches 52 from the circumferential path 51 to a vertical flow path 53.

The vertical flow path 53 connects the radial branches 52 to other radial branches 54 between the intermediate plate 423 and the lower heat conductive plate 421. Accordingly, the refrigerant reached to vertical flow path 53 flows into the radial branches 54. Consecutively, the refrigerant flows in the radial branches 54 from the vertical flow plate 421 to another circumferential path 55.

After the circumferential path 55 is filled with the refrigerant, the refrigerant returns to the refrigerant circulating apparatus through the refrigerant outlet 314. In this event, the hinder member 426 stops the refrigerant from going into the refrigerant inlet 313 while the hinder member 427 stops the refrigerant from going into between the intermediate plate 423 and the upper heat conductive plate 41.

As mentioned above, the refrigerant flows in the flow path formed at the inside of the refrigerating plate 31 and exchanges heat with the refrigerating plate 31. Therefore, the refrigerating plate 31 is refrigerated under the target temperature by the refrigerant. The refrigerating plate 31 has a uniform temperature distribution because it comprises the components made of materials with the high heat conductivity.

To maintain the temperature of the refrigerating plate 31 at the target temperature, the heater 32 is supplied with an electric current. Upon supplying electric current, the heater 32 heats the refrigerating plate 31. By controlling the electric current, heat value of the heater 32 can be controlled. Thus, the heater 32 can maintains the refrigerating plate 31 at the target temperature by controlling the electric current according to the surrounding temperature. Because the semiconductor wafer substantially has a temperature equal to the temperature of the refrigerating plate 31, the temperature of the semiconductor wafer is maintained at the target temperature.

In a case of heating the semiconductor wafer up to a high temperature, the refrigerant is not supplied from the refrigerant circulating apparatus to the refrigerating plate 31. That is, the heater 32 merely heats the vacuum chucking and refrigerating plate 31 in this case.

As mentioned above, the wafer chuck of this embodiment can hold and refrigerate and/or heat the semiconductor wafer as same as the existing wafer chuck of FIG. 1. Moreover, the wafer chuck of this embodiment has only two parts (i.e. the vacuum chucking plate 31 and the ceramic base 33) that must be formed with high accuracy. Accordingly, only one joining surface between the vacuum chucking plate 31 and the ceramic base 33 requires being made with high accuracy. Thus, the manufacturing process of the wafer chuck of this embodiment is simplified comparison with that of the existing wafer chuck and thereby the production costs is lowered. In addition, it becomes easy to obtain required finishing accuracy for the wafer chuck. Furthermore, the wafer chuck has stiffness stronger than the existing wafer chuck.

While this invention has thus far been described in conjunction with the preferred embodiment thereof, it will readily be possible for those skilled in the art to put this invention into practice in various other manners. For example, the wafer chuck may be used in another apparatus, such as a wafer etching apparatus, a wafer assayer apparatus, or other semiconductor manufacturing apparatus. Furthermore, the wafer chuck may be used for refrigerating and/or heating another thin board or plate different from the semiconductor wafer.

Moreover, the upper conductive plate may be formed by a lower plate of the vacuum chucking plate comprising a plurality of components.

What is claimed is:

1. A wafer chuck for chucking and refrigerating a semiconductor wafer, comprising:
a chucking portion having an upper surface and a lower surface for chucking said semiconductor wafer on said upper surface; and
a refrigerating portion laid on said lower surface of said chucking portion and having a flow path at the inside thereof for refrigerating said semiconductor wafer through said chucking portion by passing refrigerant through said flow path;
wherein said chucking portion is used to form a part of said flow path.

2. A wafer chuck as claimed in claim 1, wherein said wafer chuck further comprises a shell for receiving both of said chucking portion and said refrigerating portion.

3. A wafer chuck as claimed in claim 2, wherein said shell is made of stainless steel.

4. A wafer chuck as claimed in claim 1, wherein said chucking portion and said refrigerating portion are made of an aluminum alloy or a copper alloy.

5. A wafer chuck as claimed in claim 1, said refrigerating portion having a lower surface, wherein said wafer chuck further comprises:
a base having at least one protruding portion on an upper surface thereof and fixed to said lower surface of said refrigerating portion with said protruding potion for supporting said refrigerating portion and for forming a space between said lower surface of said refrigerating portion and said upper surface thereof; and
a rubber heater attached to said lower surface of said refrigerating portion in said space.

6. A wafer chuck as claimed in claim 1, wherein said refrigerating portion comprising:
a lower heat conductive plate located in parallel with said lower surface of said chucking portion; and
an intermediate portion fixed to both said chucking portion and said lower heat conductive plate for forming said flow path between said lower surface of said chucking portion and said lower heat conductive plate.

7. A wafer chuck as claimed in claim 6, wherein said intermediate portion comprises:
an intermediate plate located in parallel with said upper heat conductive plate and said lower heat conductive plate; and
a plurality of partition members located between said upper heat conductive plate and said intermediate plate and between said lower heat conductive plate and said intermediate plate for forming branches in said flow path.

8. A wafer chuck as claimed in claim 1, wherein said chucking portion provides:
concentric circular grooves on an upper surface thereof;
an evacuating bore formed at the inside thereof and extending from an outer circumferential surface thereof to about center thereof; and
connecting holes for connecting said concentric circular grooves and said evacuating bore.

9. A wafer refrigerating plate for use in a wafer chuck, comprising:
an upper heat conductive plate having an upper surface and a lower surface for chucking a semiconductor wafer on said upper surface;
a lower heat conductive plate having an upper surface and located under said upper heat conductive plate parallel to said upper heat conductive plate; and
an intermediate portion located between said upper heat conductive plate and said lower heat conductive plate and fixed to said lower surface of said upper heat conductive plate and said upper surface of said lower heat conductive plate for forming a flow path between said lower surface of said upper heat conductive plate and said upper surface of said lower heat conductive plate to pass a refrigerant through.

10. A wafer refrigerating plate as claimed in claim 9, wherein said refrigerating plate further comprises a shell for receiving both of said upper heat conductive plate, said lower heat conductive plate and said intermediate portion.

11. A wafer refrigerating plate as claimed in claim 10, wherein said shell is made of stainless steel.

12. A wafer refrigerating plate as claimed in claim 9, wherein said upper heat conductive plate, said lower heat conductive plate and said intermediate portion are made of an aluminum alloy or a copper alloy.

13. A wafer refrigerating plate as claimed in claim 9, wherein said intermediate portion comprises:
an intermediate plate located in parallel with said upper heat conductive plate and said lower heat conductive plate; and
a plurality of partition members located between said upper heat conductive plate and said intermediate plate and between said lower heat conductive plate and said intermediate plate for forming branches in said flow path.

14. A wafer refrigerating plate as claimed in claim 9, wherein said upper heat conductive plate provides:
concentric circular grooves on an upper surface thereof;
an evacuating bore from an outer circumferential surface thereof to about center thereof; and
connecting holes for connecting said concentric circular grooves and said evacuating bore.
